(19) United States
(12) Patent Application Publication
(10) Pub. No.: US 2023/0080564 A1
(43) Pub. Date: Mar. 16, 2023

(54) MULTIPLE COUPLER PLACEMENTS IN ADVANCED TRANSMIT ARCHITECTURES

(71) Applicant: SKYWORKS SOLUTIONS, INC., Irvine, CA (US)

(72) Inventors: David Richard Pehlke, Westlake Village, CA (US); Jeffrey Gordon Strahler, Greensboro, NC (US); Roman Zbigniew Arkiszewski, Oak Ridge, NC (US)

(21) Appl. No.: 17/943,659

(22) Filed: Sep. 13, 2022

Related U.S. Application Data
(60) Provisional application No. 63/356,581, filed on Jun. 29, 2022.
(60) Provisional application No. 63/244,361, filed on Sep. 15, 2021.

(51) Int. Cl. H03F 3/24; H03F 3/195; H03F 1/56; H03F 3/72

(52) U.S. Cl. CPC H03F 3/245; H03F 3/195; H03F 1/56; H03F 3/72; H03F 2200/451; H03F 2203/7209; H03F 2200/207

(57) ABSTRACT

A front-end module including a power amplifier, first and second couplers, an antenna switch, and a switch sub-assembly. The power amplifier has an input to receive a radio frequency signal and an output to provide an amplified radio frequency signal. The first coupler has an input port coupled to the output of the power amplifier, an output port coupled to an input of the antenna switch, a coupled port, and an isolated port. The second coupler has an input port coupled to an output of the antenna switch, an output port coupled to an antenna port, a coupled port, and an isolated port. The switch sub assembly connects one of the coupled port and the isolated port of the second coupler to an output of the switch assembly and the other one of the coupled port and the isolated port of the second coupler to a first termination impedance.

### CROSS-REFERENCE TO RELATED APPLICATIONS

This application claims priority under 35 U.S.C. § 119(e) to U.S. Provisional Application Ser. No. 63/244,361, titled “MULTIPLE COUPLER PLACEMENTS IN ADVANCED TRANSMIT ARCHITECTURES,” filed on Sep. 15, 2021, and to U.S. Provisional Application Ser. No. 63/356,581, titled “MULTIPLE COUPLER PLACEMENTS IN ADVANCED TRANSMIT ARCHITECTURES,” filed on Jun. 29, 2022, each of which is hereby incorporated by reference in its entirety.

### BACKGROUND

Wireless devices generate electromagnetic (EM) signals, typically within the electromagnetic spectrum at a Radio Frequency (RF) capable of propagating to other wireless devices for communication purposes. When an electromagnetic signal generated by a source is provided to a load, such as to an antenna, a portion of the signal can be reflected back from the load. An electromagnetic coupler can be included in a signal path between the source and the load to provide an indication of forward power of the electromagnetic signal traveling from the source to the load and/or an indication of reverse power reflected back from the load. Electromagnetic couplers include, for example, directional couplers, bi-directional couplers, multi-band couplers (e.g., dual band couplers), and the like.

An EM coupler typically has an input port, an output port, a coupled port, and an isolated port. When a termination impedance is presented to the isolated port, an indication of forward EM power traveling from the input port to the output port is provided at the coupled port. When a termination impedance is presented to the coupled port, an indication of reverse EM power traveling from the output port to the input port is provided at the isolated port. The termination impedance is typically implemented as a 50 Ohm shunt resistor in a variety of conventional EM couplers.

An EM coupler has a coupling factor, which represents how much power is provided to the coupled port of the EM coupler relative to the power of an EM signal at the input port. EM couplers typically cause an insertion loss in an EM signal path. Thus, an EM signal received at the input port of an EM coupler generally has a lower power when provided at the output port of the EM coupler. Insertion loss can be due to a portion of the EM signal being provided to the coupled port (or to the isolated port) and/or to losses associated with the main transmission line of the EM coupler. In addition, traditional EM couplers add insertion loss to a signal path even when unused. This can degrade an EM signal even when the EM coupler is not being used to detect power.

### SUMMARY OF INVENTION

According to at least one embodiment is provided a front-end module comprising a power amplifier configured to amplify a radio frequency signal, the power amplifier having an input configured to receive the radio frequency signal and an output configured to provide an amplified radio frequency signal, a first coupler having an input port, an output port, a coupled port and an isolated port, the input port being coupled to the output of the power amplifier, an antenna switch module having an input coupled to the output port of the first coupler and an output, a second coupler having an input port, an output port, a coupled port and an isolated port, the input port of the second coupler being coupled to the output of the antenna switch module, an antenna port configured to be coupled to an antenna, the antenna port being coupled to the output port of the second coupler, and a first switch sub assembly to switchably connect one of the coupled port and the isolated port of the second coupler to an output of the first switch assembly and the other one of the coupled port and the isolated port of the second coupler to a first termination impedance.

In one example, the isolated port of the first coupler is connected to a second termination impedance.

In another example, the front-end module further comprises a second switch sub assembly to switchably connect one of the coupled port and the isolated port of the first coupler to an output of the second switch assembly and the other one of the coupled port and the isolated port of the first coupler to a second termination impedance.

In one example, the front-end module further comprises a filter connected between the output port of the first coupler and the input of the antenna switch module.

In another example, the front-end module, further comprises a controller coupled to the first switch sub assembly and the second switch sub assembly and configured to connect the coupled port of the first coupler to the output of the second switch assembly and to connect the isolated port of the first coupler to the second termination impedance to obtain a first measurement from the output of the second switch assembly, the first measurement providing an indication of forward power provided by the power amplifier.

In one example, the controller is further configured to connect the coupled port of the second coupler to the output of the first switch assembly and to connect the isolated port of the second coupler to the first termination impedance to obtain a second measurement from the output of the first switch assembly, the second measurement providing an indication of forward power present on the antenna.

In another example, the controller is further configured to connect the isolated port of the second coupler to the output of the first switch assembly and to connect the coupled port of the second coupler to the first termination impedance to obtain a second measurement from the output of the first switch assembly, the second measurement providing an indication of power reflected from the antenna.

In one example, the controller is further configured to adjust an impedance of the antenna based on the indication of power reflected from the antenna.

In another example, the controller is further configured to obtain a first measurement from the output port of the first coupler and a second measurement from the output port of the second coupler.

In one example, the controller is further configured to linearize the amplified radio frequency signal by modifying, based on the first measurement and the second measurement, the radio frequency signal received by the power amplifier.

In another example, the controller is further configured to determine, based on the first measurement and the second measurement, an amplitude and a phase of a transfer function that describes a change in power of the amplified radio frequency signal between the power amplifier and the antenna.

In one example, the controller is further configured to operate the switch assembly to obtain a measurement of forward power provided to the antenna, operate the switch assembly to obtain a measurement of reflected power from the antenna, calculate a ratio between the measurement of forward power and the measurement of reflected power, and adjust an amount of power provided by the power amplifier based on the calculated ratio.

In another example, the front-end module further comprises a second power amplifier configured to amplify a second radio frequency signal, the second power amplifier having an input configured to receive the second radio frequency signal and an output configured to provide a second amplified radio frequency signal, a third coupler having an input port, an output port, a coupled port and an isolated port, the input port of the third coupler being coupled to the output of the second power amplifier and the output port of the third coupler being coupled to a second input of the antenna switch module, a fourth coupler having an input port, an output port, a coupled port and an isolated port, the input port of the fourth coupler being coupled to a second output of the antenna switch module and a second antenna port configured to be coupled to a second antenna, the second antenna port being coupled to the second output of the second coupler.

In one example, the power amplifier, the first coupler, the second coupler, and the antenna port form a first chain, the second power amplifier, the third coupler, the fourth coupler, and the second antenna port form a second chain, and the amplified radio frequency signal of the first chain is in a different frequency band than the second amplified radio frequency signal of the second chain.

In another example, the amplified radio frequency signal and the second amplified radio frequency signal are transmitted at the same time.

In one example, the radio frequency signal received by the input of the power amplifier has a frequency in one of a range of about 600 MHz to about 2.5 GHz, a range of about 450 MHz to about 6 GHz, and a range of about 24 GHz to 52 GHz.

In another example, the first coupler is a unidirectional coupler and the second coupler is a bidirectional coupler.

According to at least one embodiment there is provided a front-end module comprising a power amplifier configured to amplify a radio frequency signal, the power amplifier having an input configured to receive the radio frequency signal and an output configured to provide an amplified radio frequency signal, a first coupler having an input port, an output port, a coupled port and an isolated port, the input port being coupled to the output of the power amplifier, an antenna switch module having an input coupled to the output port of the first coupler and an output, a second coupler having an input port, an output port, a coupled port and an isolated port, the input port of the second coupler being coupled to the output of the antenna switch module, an antenna port configured to be coupled to an antenna, the antenna port being coupled to the output port of the second coupler, and a first switch sub assembly to switchably connect one of the coupled port and the isolated port of the second coupler to an output of the second switch assembly and the other one of the coupled port and the isolated port of the second coupler to a second termination impedance, or to connect each of the coupled port and the isolated port of the second coupler to the second termination impedance.

In one example, the isolated port of the first coupler is connected to a second termination impedance.

In another example, the front-end module further comprises a second switch sub assembly to switchably connect one of the coupled port and the isolated port of the first coupler to an output of the second switch assembly and the other one of the coupled port and the isolated port of the first coupler to a second termination impedance.

In one example, the front-end module further comprises a filter connected between the output port of the first coupler and the input of the antenna switch module.

In another example, the front-end module further comprises a controller coupled to the first switch sub assembly and the second switch sub assembly and configured to connect the coupled port of the first coupler to the output of the second switch assembly and to connect the isolated port of the first coupler to the second termination impedance to obtain a first measurement from the output of the second switch assembly, the first measurement providing an indication of forward power provided by the power amplifier.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a block diagram of one example of an electronic system including a coupler placed between a power amplifier and a filter;

FIG. 2 is a block diagram of one example of an electronic system including a coupler placed between an antenna switch module and an antenna port;

FIG. 3 is a block diagram of one example of an electronic system including a first coupler and a second according to aspects of the present invention;

FIG. 4A is a circuit diagram of one example of a switch assembly according to aspects of the present invention;

FIG. 4B is a circuit diagram of one example of a switch assembly according to aspects of the present invention;

FIG. 5A is a block diagram of one example of an electronic system including multiple transmission lines that each include a first coupler and a second coupler according to aspects of the present invention;

FIG. 5B is a block diagram of one example of an electronic system including multiple transmission lines that each include a first coupler and a second coupler according to aspects of the present invention;

FIG. 6 is a circuit diagram of one example of an electronic system that transmits in two different bands according to aspects of the present invention;

FIG. 7 is a circuit diagram of one example of an electronic system that transmits in two different bands according to aspects of the present invention; and

FIG. 8 is a circuit diagram of one example of an electronic system that transmits in two different bands according to aspects of the present invention.

### DETAILED DESCRIPTION

Radio frequency (RF) couplers or electromagnetic (EM) couplers can be used in modern cellular and connectivity transmit architectures to 1) measure accurate forward power to optimize uplink transmit radiated power (TRP), signal-to-noise-ratio (SNR), DC efficiency, and linearity, 2) be used as part of a closed loop power control system that adaptively corrects to maintain a known and/or constant power level, 3) measure reflected power as an indicator of the mismatch load variation on the transmit antenna, 4) measure both forward and reflected power as a means to determine the complex impedance of the antenna in an effort to adjust and re-tune to improve the load impedance, and 5) measure the out-of-channel emissions of the power amplifier in order to adaptively correct linearity through techniques of analog stimulus change and/or digital pre-distortion (DPD) techniques.

In some instances, the coupler can be placed either 1) immediately after the power amplifier (PA) and before the acoustic filtering in order to get as accurate a picture of the power amplifier linearity/emissions/impedance environment as possible for closed-loop/DPD considerations, or the coupler can be placed 2) close to the antenna to get as close as possible to the exact forward/reflected power present on the antenna. Conventional implementations of the coupler introduces insertion loss and size/cost to the overall transmit path.

As the coupling factor of the coupler becomes more controlled with complex impedance terminations on the unused port that can significantly improve directivity and frequency dependence, the insertion loss of the coupler and size can be optimized. Whether integrated in the laminate/FR4 PCB metal traces with switching and termination controls in the silicon on insulator (SOI) die of a Band Select switch or antenna switch module (ASM), or entirely integrated within the SOI die of the Band Select Switch or ASM, the coupler can be made small and integrated with stacked and/or 3-dimensional packaging technologies to further reduce size and improve quality factor (Q) and insertion loss. As described in embodiments presented herein, a multiple placement architecture of two couplers (one immediately after the PA for optimal DPD and power amplifier (PA) linearity adjustment/out-of-band emissions correction, and one after the ASM for improved proximity to the load antenna for power accuracy) is provided. As the insertion loss becomes lower, the use of both couplers for these different applications becomes viable, and even concurrent measurement is made possible with solutions provided herein. Each of these couplers provides access to the optimal measurements needed for the entire set of needs for DPD and emissions correction right at the output of the PA as well as the measurements closer to the antenna for power accuracy and antenna tuning, etc.

An additional benefit of the two-coupler design is that it facilitates a complete understanding of the transfer function that describes the transmit path from the output of the PA to the antenna. This, in turn, enables adding DPD with certainty since the transfer function is known. Every component along the transmit path that the input signal encounters will affect or distort the signal in some way. There is therefore a transfer function for each component that describes how the signal is changed by the component. By knowing the power of the signal in the transmit path at the first coupler and at the second, the transfer function of the overall transmit path may be estimated by determining a transfer function that describes the change in power between the first and second couplers.

Both couplers may be used concurrently to measure 1) the precise complex transfer function between the power amplifier and the antenna pin of an integrated module, offering precise measurement of the in-band transmit (Tx) filter contour and S21+ASM insertion loss characteristics in each band and for each Tx path (whereas prior art single coupler modules do not provide access to this or the signals on internal nodes), 2) the out-of-band attenuation and harmonic characteristics of the Tx path, 3) complex transfer function characteristics of the entirety of blocks between the couplers for RF development and tuning, and 4) enabling programmable adjustment to shunt inductors and LPF/notches that may improve/adjust the filter contours/mismatch insertion loss and out-of-band attenuations. These can be used in sequence one at a time, or concurrently for combined data analytics by the feedback receiver and modem baseband, eventually enabling more dynamic adjustment as the blocks become more programmable and tunable and measurements are required for optimal setting of tunable transmit components.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation.

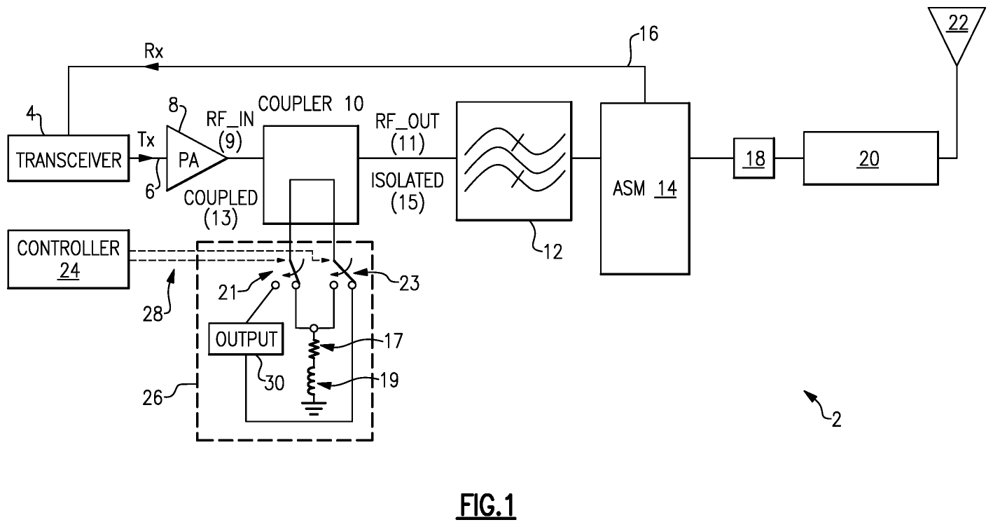

FIG. 1 is schematic block diagram of one example of an electronic system 2 in which an EM coupler 10 is configured to extract a portion of power of an EM signal traveling between a transceiver 4 and an antenna 22. The electronic system 2 may be included in a front-end module. In this example, the EM coupler 10 is a bi-directional coupler. As illustrated, in the forward or transmit direction, a power amplifier 8 receives an EM signal 6 from the transceiver 4 and provides an amplified EM signal to the antenna 22 by way of the EM coupler 10 operating in the forward mode, a filter 12, an antenna switch module (ASM) 14, and an antenna port 18. In some examples, the filter 12 is a surface acoustic wave filter. It will be understood by those skilled in the art that additional elements (not illustrated) can be included in the electronic system of FIG. 1 and/or a sub combination of the illustrated elements can be implemented. Further, components of the system 2 may be arranged in an order different from that shown in FIG. 1. The electronic system 2 includes a loss 20 between the antenna port 18 and the antenna 22 that is attributed to the components in the transmission path between the filter 12 and the antenna 22. Some examples of the loss 20 include a resistive and inductive (or capacitive) shunt that is connected to the antenna port 18 and antenna 22.

Referring still to FIG. 1, the EM coupler 10 typically has a power input port 9 (RF_IN), a power output port 11 (RF_OUT), a coupled port 13 (COUPLED), and an isolated port 15 (ISOLATED). The electromagnetic coupling mechanism, which can include inductive or capacitive coupling, is typically provided by two parallel or overlapped transmission lines, such as microstrips, strip lines, coplanar lines, and the like. A main transmission line extends between the power input port 9 and the power output port 11 and provides the majority of the signal from the power input port 9 to the power output port 11. A coupled line extends between the coupled port 13 and the isolated port 15 and may extract a portion of the power traveling between the power input port 9 and the power output port 11 for various purposes, including various measurements. When a termination impedance is presented to the isolated port 15, an indication of forward RF power traveling from the power input port 9 to the power output port 11 is provided at the coupled port 13.

The antenna switch module 14 can selectively electrically connect the antenna 22 to a selected transmit path Tx or a selected receive path Rx 16. The antenna switch module 14 can provide a number of switching functionalities. The antenna switch module 14 can include a multi throw switch configured to provide functionalities associated with, for example, switching between transmit and receive modes, switching between transmit or receive paths associated with different frequency bands, switching between transmit or receive paths associated with different modes of operation, or any combination thereof.

The power amplifier 8 amplifies the EM signal 6 received from the transceiver. The power amplifier 8 can be any suitable EM power amplifier. For example, the power amplifier 8 can include one or more of a single stage power amplifier, a multi-stage power amplifier, a power amplifier implemented by one or more bipolar transistors, or a power amplifier implemented by one or more field effect transistors. The power amplifier 8 can be implemented on a GaAs die, CMOS die, or a SiGe die, for example.

The antenna 22 can transmit the amplified EM signal and receive EM signals. For example, when the electronic system 2 is included in a cellular phone, the antenna 2 can transmit an EM signal from the cellular phone to a base station, and similarly receive EM signals from the base station.

When the electronic system illustrated in FIG. 1 is operating in a transmit mode, the EM coupler 10 can extract a portion of the RF signal power traveling between the power amplifier 8 and the antenna 22. The EM coupler 10 can generate an indication of forward RF power traveling from the power amplifier 8 to the antenna 22 and/or generate an indication of reflected (reverse) power traveling from the antenna 22 to the power amplifier 8. An indication of forward or reflected power at the output 30 can be provided to a power detector (not illustrated). The EM coupler 10 has four ports, namely, the input port 9 (RF_IN), the output port 11 (RF_OUT), the coupled port 13, and the isolated port 15. In the configuration of system 2 shown in FIG. 1, the input port 9 can receive the amplified EM signal from the power amplifier 8 and the output port 11 can provide the amplified EM signal to the antenna 22. A termination impedance can be connected to the isolated port 15 (for forward operation) or to the coupled port 13 (for reverse operation). When the termination impedance is connected to the isolated port 15, the coupled port 13 can provide a portion of the power of the EM signal traveling from the input port 9 to the output port 11. Accordingly, the coupled port 13 can provide an indication of forward EM power. When the termination impedance is connected to the coupled port 13, the isolated port 15 can provide a portion of the power of the EM signal traveling from the output port 11 to the input port 9. Accordingly, the isolated port 15 can provide an indication of reverse EM power.

The placement of the EM coupler 10 immediately after the power amplifier 8 provides optimal measurement of power being provided by the power amplifier 8 without affecting the Rx signal path. For example, while not shown in FIG. 1, the Rx path could be a separate receive path coupled to the antenna port 18 and including a low noise amplifier (LNA), optionally with a receive filter therebetween, or a separate receive path coupled to a second port of the ASM. Other advantages are afforded by placing the EM coupler 10 in this position. For example, this placement facilitates an accurate adjacent channel leakage ratio (ACLR), which is the ratio of the transmitted power to the power measured after a receiver filter in the adjacent channel(s).

To switch between generating an indication of forward power and reflected (reverse) power, a controller 24 is configured to operate a plurality of switches within a switch assembly 26 via control lines 28. The controller 24, in certain examples, is a general-purpose processor. In other examples, the controller 24 is a customized microcontroller. Other suitable examples of the controller 24 are contemplated herein. The switch assembly 26, as illustrated in FIG. 1, includes a termination impedance including a resistor 17 and an inductor 19 connected in series between a node and ground. The node is connected to one switchable terminal of each of a first single pole double throw (SPDT) switch 21 and a second single pole double throw (SPDT) switch 23. The other switchable terminal of each SPDT switch is coupled to an output 30. To generate an indication of reverse power, the controller 24 operates the first switch 21 via one or more control lines 28 to connect the coupled port 13 to the termination impedance and operates the second switch 23 via the one or more control lines 28 to connect the isolated port to the output 30. In some examples, the output 30 is coupled to the controller 24 and provides the indication of reverse power to the controller. In other examples, the output 30 is coupled to a separate electronic device (not shown) for processing the data obtained from the output 30. To generate an indication of forward power, the controller 24 operates the first switch 21 via the control lines 28 to connect the coupled port 13 to the output 30 and operates the second switch 23 via the control lines 28 to connect the isolated port 15 to the termination impedance. Although shown in FIG. 1 as having fixed values, it is understood that a variable resistor, variable inductor, and/or a variable capacitor connected in series to ground may be used in place of the illustrated termination impedance to thereby provide a variable termination impedance. As a result, the termination impedance can be tuned to adjust the resistance, capacitance, inductance, and/or combinations to thereby provide a desired termination impedance to the respective ports. Such tunability can be advantageous for post-design configuration, compensation, and/or optimization.

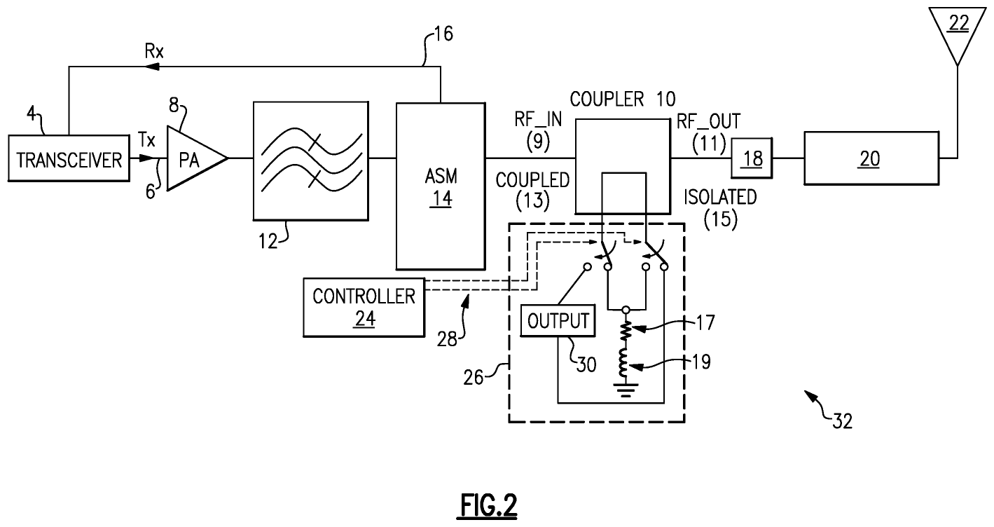

FIG. 2 is schematic block diagram of one example of an electronic system 32 in which the EM coupler 10 is coupled close to the antenna 22. The electronic system 32 may be included in a front-end module. Other than this difference with FIG. 1, the remaining features of the system 32 are identical to those illustrated in FIG. 1 and described above, so redundant explanation of the same elements will be omitted for the sake of brevity. As shown in FIG. 2, the input port 9 of the EM coupler 10 is coupled to an output of the antenna switch module 14 and the output port 11 of the EM coupler is coupled to the antenna switch port 18.

The placement of the EM coupler 10 after the antenna switch module 14 and close to the antenna 22 provides accurate measurement of power provided to the antenna 22, which is useful in impedance matching and voltage standing ratio (VSWR) calculations. VSWR is a measure of how efficiently radio-frequency power is transmitted from a power source, through a transmission line, and into a load (e.g., an antenna).

As illustrated, in the forward or transmit direction, the power amplifier 8 receives the EM signal 6 from the transceiver 4 and provides the amplified EM signal to the antenna 22 by way of the filter 12, the antenna switch module 14, the EM coupler 10 operating in the forward mode, and the antenna port 18. Similarly, in the receive direction, a received EM signal Rx is provided from the antenna 22 to the transceiver 4 via the EM coupler 10 (operating in the reverse mode) and the antenna switch module 14. It will be understood by those skilled in the art that additional elements (not illustrated) can be included in the electronic system 32 of FIG. 2 and/or a sub combination of the illustrated elements can be implemented. Further, components of the system may be arranged in an order different from that shown in FIG. 2.

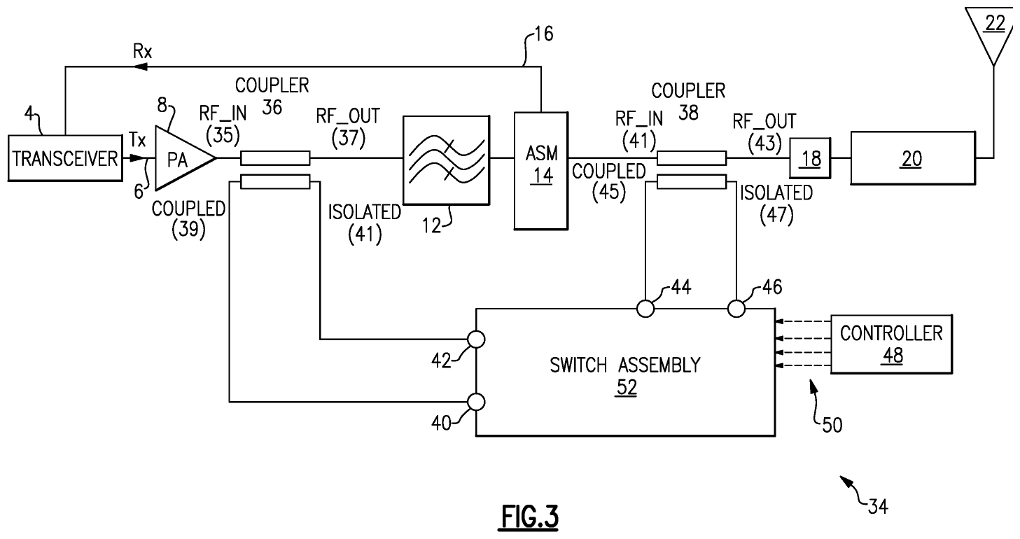

FIG. 3 is a block diagram of one example of an electronic system 34 including a first EM coupler 36 coupled between or near the output of the power amplifier 4 and filter 12 in a similar fashion to the EM coupler 10 shown in FIG. 1, and a second EM coupler 38 placed between the antenna switch module 14 and the antenna port 18 in a similar fashion to the EM coupler 10 shown in FIG. 2. The electronic system 34 may be included in a front-end module. As shown in FIG. 3, the first EM coupler 36 and the second EM coupler 38 are bi-directional couplers. However, in other embodiments, one or both of the first EM coupler 36 and the second EM coupler 38 may be a unidirectional or forward only coupler. A unidirectional coupler is an example of a forward only coupler and has three ports: an input port, an output port, and a coupled port.

By combining the EM coupler implementations shown in FIGS. 1-2 into a single electronic system 34, the system 34 not only includes all of the advantages of placing an EM coupler closer to the power amplifier and placing an EM coupler close to the antenna 22, but the combination also results in advantages unique to the system 34.

The first EM coupler 36 includes an input port (RF_IN) 35, an output port (RF_OUT) 37, a coupled port 39, and an isolated port 41. The second EM coupler 38 includes an input port (RF_IN) 41, an output port (RF_OUT) 43, a coupled port 45, and an isolated port 47. To control the coupling direction of each of the first EM coupler 36 and the second EM coupler 38, a controller 48 is connected to a switch assembly 52 via one or more control lines 50. The controller 48, in certain examples, is a general-purpose processor. In other examples, the controller 48 is a customized microcontroller. Other suitable examples of the controller 48 are contemplated herein. Switch assembly 52 includes four terminals: a first terminal 40 configured to be coupled to the coupled port 39 of the first EM coupler 36, a second terminal 42 configured to be coupled to the isolated port 41 of the first EM coupler 36, a third terminal 44 configured to be coupled to the coupled port 45 of the second EM coupler 38, and a fourth terminal 46 configured to be coupled to the isolated port 47 of the second EM coupler 38.

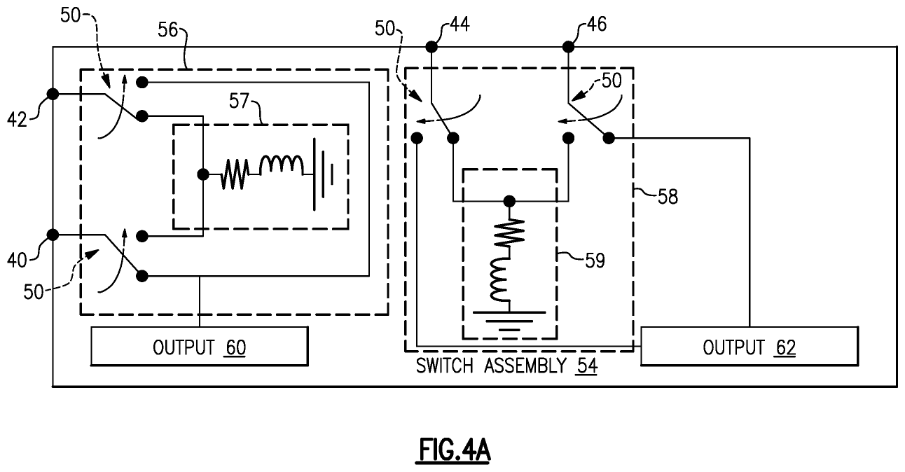

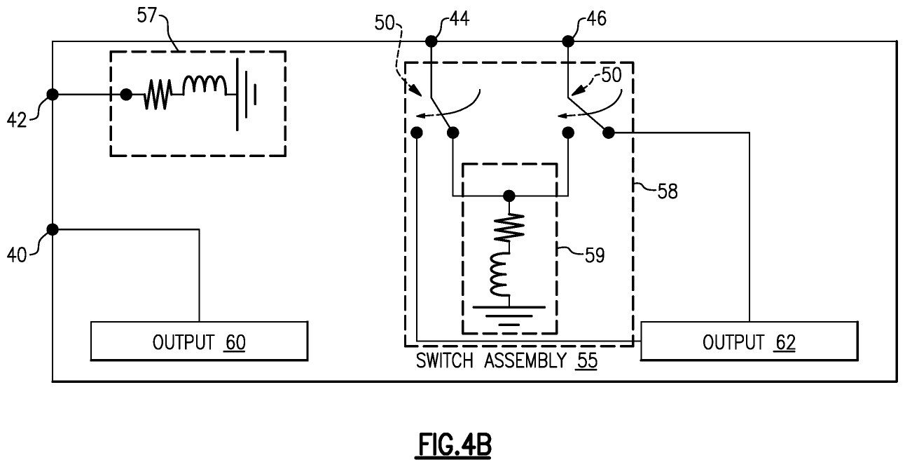

FIG. 4A is a circuit diagram of one example of a switch assembly 54. In some examples, the switch assembly 54 is identical to the switch assembly 52. The switch assembly 54 includes the first terminal 40, second terminal 42, third terminal 44, and fourth terminal 46. As shown in FIG. 4A, the switch assembly 54 includes a first switch sub assembly 56 and a second switch sub assembly 58, which individually operate in the same manner as the switch assembly 26 described above. Like the output 30, each of the switch sub assemblies is configured to couple either the coupled or isolated port of the respective EM coupler to an output. The first switch sub assembly 56 is configured to couple one of the coupled port 39 and isolated port 41 to an output 60 and the other port to a termination impedance 57. The second switch sub assembly 58 is configured to couple one of the coupled port 45 and isolated port 47 to an output 62 and the other port to a termination impedance 59. Each of the SPDT switches shown in FIG. 4A is configured to be operated via one or more control lines 50, which are connected to a controller (e.g., the controller 48).

In examples of one of the first EM coupler 36 or the second EM coupler 38 being a three-port unidirectional coupler (not shown), the corresponding switch sub assembly 56, 58 would require only one SPDT switch for the three-port coupler to be operated by a controller. To save production cost, in an example, the first EM coupler 36 may be a unidirectional coupler with a coupled port connected to the switch assembly 52 via a single terminal of the first and second terminals 40, 42. In some examples, one or both of the first EM coupler 36 and the second EM coupler 38 is unidirectional and has no switches. In one example, only the first EM coupler is unidirectional (forward only) with no switches and the second EM coupler 38 is bi-directional with at least one switch. The second coupler 38 may be a bidirectional coupler. As a consequence, the first switch sub assembly 56 would only require one SPDT switch (not shown) configured to be controlled via a control line 50 to switch between the output 60 and the termination impedance 57.

FIG. 4B is a circuit diagram of one example of a switch assembly 55 that shares several components in common with the switch assembly 54, so a detailed explanation of the identical comments will not be repeated for the sake of brevity. The switch assembly 55 differs from the switch assembly 54 in that the first terminal 40 is directly coupled to the output 60 and the second terminal 42 is directly coupled to the termination impedance 57. In examples where the first EM coupler 36 is a unidirectional coupler that is hardwired to be unidirectional, and thus has no switches, the switch assembly 55 may be used with the unidirectional first coupler 36 and a bidirectional second coupler 38.

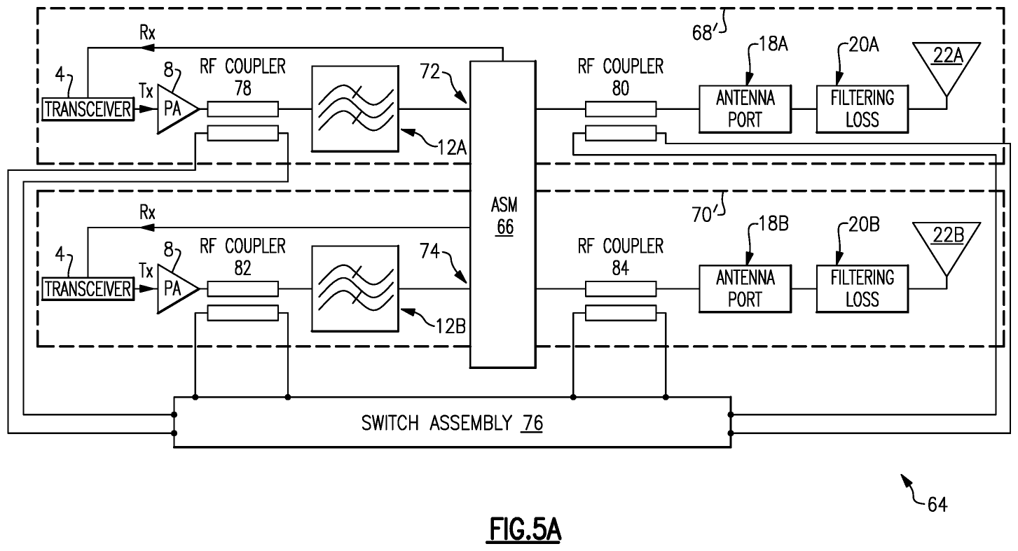

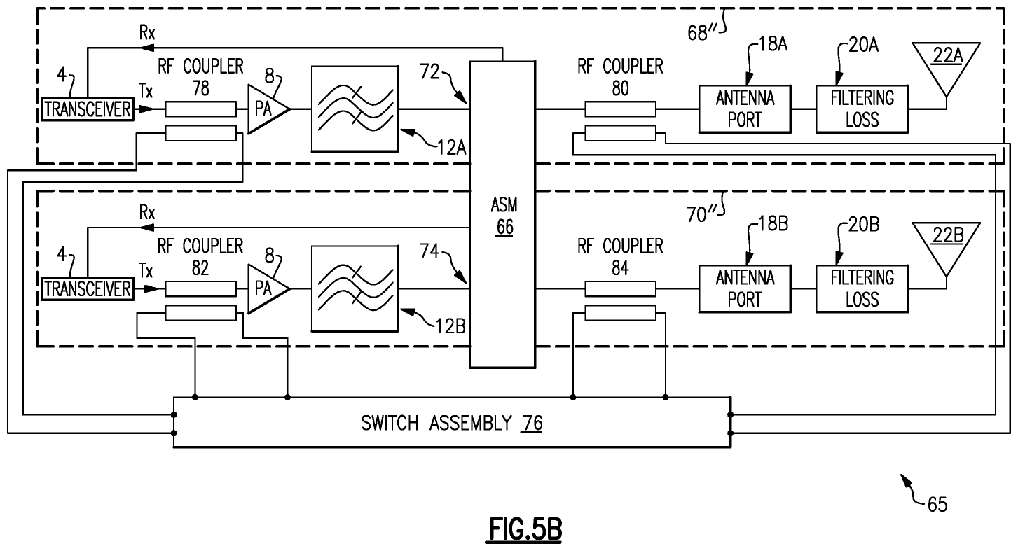

FIG. 5A is a block diagram of one example of an electronic system 64 including multiple transmit chains, each transmit chain 68′, 70′ including multiple EM couplers sharing a single antenna switch module 66 and a switch assembly 76. The switch assembly 76 includes a plurality of internal switches that are selectively coupled to all or a subset of electromagnetic (EM) couplers in the electronic system 64. The internal switches are operated by a controller. The electronic system 64 may be included in a front-end module. The multiple transmit chains shown in FIG. 5A include a first transmit chain 68′ connected to an antenna switch module 66 at a first antenna switch module input 72 and a second transmit chain 70′ connected to the antenna switch module 66 at a second antenna switch module input 74. Each transmit chain includes two EM couplers, thereby providing a first EM coupler 78 and a second EM coupler 80 in the first transmit chain 68′, and a third EM coupler 82 and a fourth EM coupler 84 in the second transmit chain 70′. The second EM coupler 80 is coupled to a first antenna port 18A, which is coupled to a first antenna 22A via a filtering loss 20A. The fourth EM coupler 84 is coupled to a second antenna port 18B, which is coupled to a second antenna 22B via a filtering loss 20B. The first EM coupler 78 and the third EM coupler 82 are coupled to the outputs of their respective power amplifiers to have relatively less impact on the transmission path of each transmit chain as opposed to placing the couplers before the respective power amplifiers. However, as discussed in more detail below, there are also advantages to placing the couplers before the power amplifiers. In certain embodiments, one or more of the first transmit chain 68′ and the second transmit chain 70′ includes components that are identical to the transceiver 4, power amplifier 8, first EM coupler 36, filter 12, second EM coupler 38, antenna port 18, and antenna 22, with the antenna switch module 66 including additional ports for each transmit chain. It is understood that the two transmit chains 68′, 70′ shown in FIG. 5A are only one example of an electronic system, and embodiments described herein may include electronic systems having more than two transmit chains.

FIG. 5B is a block diagram of one example of an electronic system 65 including multiple transmit chains including multiple EM couplers sharing the antenna switch module 66 and switch assembly 76. The electronic system 65 differs from the electronic system 64 shown in FIG. 5A in that the electronic system 65 includes a first transmit chain 68″ and a second transmit chain 70″ where the first transmit chain 68″ includes the first EM coupler 78 coupled between the transceiver and the power amplifier of the first transmit chain 68″ and the second transmit chain 70″ includes the third EM coupler 82 coupled between the transceiver and the power amplifier of the second transmit chain 70″. One reason to place an EM coupler closer to the transceiver is to avoid or at least lessen the impact of non-linearities introduced into the transmission path of the RF signal by the transceiver (and any other upstream equipment), thereby preventing additional noise being added to the signal as it is amplified, filtered, and processed.

In both the electronic system 64 and the electronic system 65, the first EM coupler 78 is placed in the first transmit chain 68′, 68″ before the antenna switch module 66 before the signal produced by the power amplifier in the first transmit chain 68′, 68″ is filtered by a filter 12A. Similarly, the third EM coupler 82 is placed in the second transmit chain 70′, 70″ before the antenna switch module 66 and before the signal produced by the power amplifier in the second transmit chain 70′, 70″ is filtered by a filter 12B. By placing the couplers in this way, forward power going into the filters and/or power amplifiers is able to be more accurately detected. When the antenna of a transmit chain is loaded and detunes due to interaction with an RF signal, changes are produced in the power amplifier of the transmit chain. These changes include an increase in the power of the signal provided to the filter. Each filter may have a specified operating range including a maximum input power. Without being able to monitor the amount of power being provided to the filter, the filter could exceed its specified operating range and be damaged as a result. Accordingly, to ensure forward power does not reach a level that would cause the filter to be damaged or exceed a maximum temperature limit, for example, the electronic systems 64, 65 monitor forward power via the EM couplers 78, 82 placed before the filtering (as shown in FIG. 5A) and band switching occurs in the transmission path of each transmit chain. While forward power could be deduced using an EM coupler placed closer to the antenna of a transmit chain, placement of the EM coupler closer to the transceiver and power amplifier affords relatively more accurate power accuracy and a faster response time to prevent the filter from being damaged. By placing the EM couplers 78, 82, immediately before the power amplifiers (as shown in FIG. 5B), power being provided to the power amplifier can be measured and if the power reaches an unsafe level, the power amplifier or the entire transmit chain can be shut down to prevent damage.

Inclusion of the EM couplers 80, 84 after the antenna switch module 66 in combination with the EM couplers 78, 82 placed before the ASM 66 affords several benefits. As Rx signals are picked up by the antenna in the first transmit chain 68″ for example, the Rx signals travel through the first antenna port 18A, the second EM coupler 80, the antenna switch module 66, and the transceiver. Placement of the EM couplers 80, 84 after the antenna switch module 66 provides more accurate measurements of Tx power being provided by the antenna than if placed before the antenna switch module 66 and closer to the power amplifier because the point of sampling is placed closer to the antenna after the Tx signal(s) have passed through the various components of a transmit chain. Ideally, the Rx signals received by the antenna do not interfere with the Tx signals being transmitted by the transceiver to the EM coupler 78, the power amplifier, and so on. However, in practice, Rx signals can leak into the Tx path due to coupling between the Rx signal(s) and components along the Tx path. The filter following the power amplifier (e.g., filters 12A and 12B in FIGS. 5A and 5B) provides at least some rejection capability to block the Rx signal in the Tx path. However, by using the second EM coupler 80 at its location shown in FIG. 5B, Rx signals from the antenna or reflected outgoing/Tx signals can be ‘sniffed’ in the Rx path before they reach and potentially damage or interfere with the power amplifier. In some examples, the second EM coupler 80 (and likewise the fourth EM coupler 84) is configured to have Rx-specific termination impedances to shunt signals carrying specific frequencies to ground, thereby preventing damage to the PA. In at least one example, the second EM coupler 80 and/or the fourth EM coupler 84 are configured to measure forward power and have a termination impedance at their reverse coupled ports. With a fixed termination impedance, each EM coupler 80, 84 is configured to block a specific RF frequency. With a variable impedance that can be controlled, the specific frequencies being blocked can be selected or changed, which is desirable when the electronic system 65 is located in an environment having signals that interfere with the Tx path(s).

Multiple transmit chains are beneficial for many applications including those requiring 5G communication. 5G mobile networks, for example, can operate in various frequencies and can require different antennas for different frequency bands. Accordingly, for a 5G application of the electronic system 64, the first transmit chain 68′, 68″ may operate in a first 5G frequency band and the second transmit chain 70′, 70″ may operate in a second 5G frequency band different than the first frequency band. In applications requiring both 4G and 5G communications, electronic systems using at least three transmit chains may be used, where two chains operate for 5G as described previously and the third chain operates for 4G communication.

The switch assembly 76 is configured receive an output from each of the EM couplers 78, 80, 82, 84. In some embodiments, one of the coupled port or the isolated port of each EM coupler 78, 80, 82, 84 is selected by the switch assembly 76 for sampling while the other port is shunted to ground by the switch assembly 76, thereby sampling either forward or reverse power from each EM coupler 78, 80, 82, 84. In certain embodiments, the switch assembly 76 includes an individual switch sub assembly for each EM coupler that is similar or identical to the switch assembly 26, thereby providing a termination impedance and an output for each EM coupler 78, 80, 82, 84.

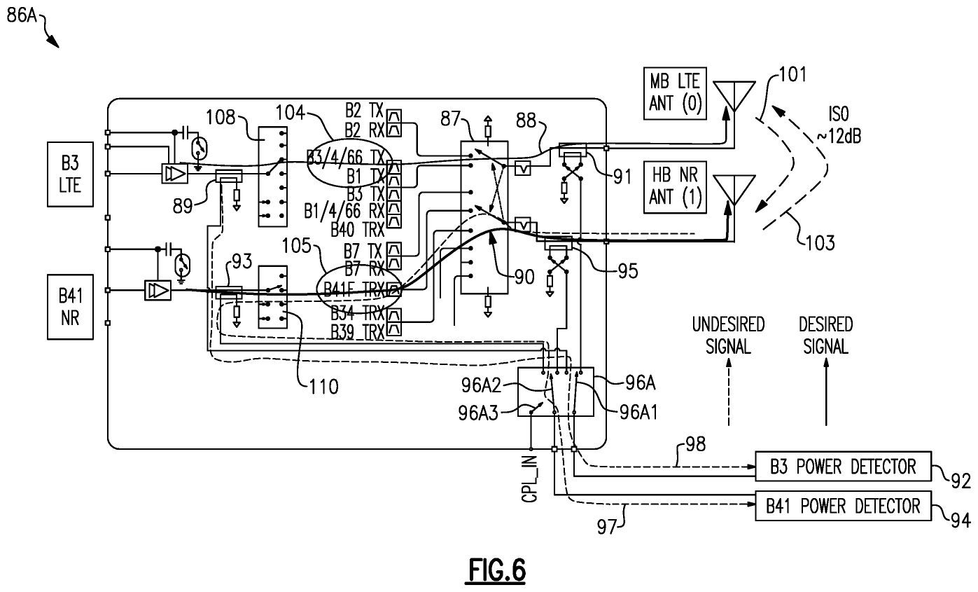

FIG. 6 illustrates an electronic system 86A including an antenna switch module 96A, a first B3 (band three or B3) coupler 89, a second B3 coupler 91, a third B41 (band forty-one or B41) coupler 93, and a fourth B41 coupler 95. In some embodiments, the electronic system 86A is part of a front-end module. Some front-end module applications require or are capable of transmission and/or reception of at least two different frequency bands at the same time. For example, some smart phones require transmitting in both 4G and 5G frequency bands. According to one example, the 4G and 5G frequency bands are both different and non-overlapping. In FIGS. 6, B3 and B41 are examples of different and non-overlapping frequency bands. Bands 3, 4, and 66 are examples of Frequency Division Duplexing (FDD) channels or bands, while bands such as Bands 34, 39, and 41 are examples of Time Division Duplexing (TDD) channels or bands. Frequency bands that operate in a frequency division duplex (FDD) mode perform simultaneous transmit (Tx) and receive (Rx) operations using different frequencies in the same band. For example, Band 3 operates with transmit signals having frequencies of approximately 2500 MHz to approximately 2570 MHz, and operates with receive signals having frequencies of approximately 2620 MHz to approximately 2690 MHz. This is typically accomplished by the use of a duplexer, which combines Tx and Rx paths into a common terminal. By contrast, frequency bands that operate in a time division duplex (TDD) mode have a single frequency band that is utilized for both Tx and Rx operations, but at different times. For example, Bands 40 and 41 operate with a single frequency band of approximately 2300 MHz to approximately 2400 MHz for Band 40, and approximately 2496 MHz to approximately 2690 MHz for Band 41.

Currently, the majority of 5G deployments utilize non-standalone (NSA) architectures. In an NSA 5G deployment, for example, certain 5G mobile devices such as smartphones are still connected to 4G LTE such that data transfer occurs over 4G LTE and 5G simultaneously. One wireless standard that implements this dual LTE/5G functionality is E-UTRAN New Radio-Dual Connectivity (ENDC). The electronic systems 64, 65, 86A may be implemented as an ENDC architecture in a wireless device used for simultaneously accessing both 5G and 4G LTE networks, thereby affording additional overall bandwidth when compared to a stand-alone (SA) 5G network.

The system 86A includes a B3 Tx signal 88 leaking into a signal path of a B41 signal 90 through the finite antenna isolation (which is typically about 12 dB). The dashed line 97 indicates undesired B3 signals that are leaking into B41 signal paths due to leakage path 101. Similarly, the dashed line 98 indicates undesired B41 signals that are leaking into B3 signal paths due to leakage path 103. As shown, the B3 signal is provided to the coupler 89 and from the coupler 89 to a band select switch 108 that routes the signal to an appropriate filter (e.g., a band 3/4/66 transmit filter) selected from among a plurality of filters and/or duplexers, filter 104. As bands 3, 4, and 66 occupy a frequency range of about 1710 MHz to about 1785 MHz, each of these bands may use a common transmit filter, for example the B3/4/66 TX filter. The B41 signal is provided to the coupler 93 and from the coupler 93 to a band select switch 110 that routes the signal to an appropriate filter, filter 105. As should be appreciated in view of FIG. 6, were the first B3 coupler 89 and the third B41 coupler 93 not present after the power amplifier in each chain, then the coupled output signal would necessarily have been provided by the coupled output of the second B3 coupler 91 and the fourth B41 coupler 95, respectively. Given the modest isolation between the two antennas (about 12 dB), the coupled B3 signal from the second B3 coupler 91 would include significant energy from B41 and the coupled B41 signal from the fourth B41 coupler 95 would include significant energy from B3. As a result, sensing accuracy at each of the power detectors is significantly compromised.

Any undesired B3 signals that are leaking into B41 signal paths, such as the signals indicated by the dashed line 97, may traverse the ASM 87 and then the B41 transmit filter 105 (which should effectively filter all but B41 signals) before being coupled to the B41 power detector 94. Similarly, any undesired B41 signals that are leaking into the B3 signal path, such as the signals indicated by the dashed line 98, may traverse the ASM 87 and then the B3/4/66 transmit filter 104 (which should effectively filter all but B3 signals) before being coupled to the B3 power detector 92. As a result, forward power detection is significantly more accurate than if detected via the second B3 coupler 91 and the fourth B41 coupler 95.

The switch assembly 96A includes a B3 switch 96A1 and a B41 switch 96A2. The B3 switch 96A1 is coupled to the B3 power detector 92 and the B41 switch 96A2 is coupled to the B41 power detector 94. Additionally, the B3 switch 96A1 is configured to switch between power provided from the coupled port of the first B3 coupler 89 or the coupled port of the second B3 coupler 91, and the B41 switch 96A2 is configured to switch between power provided from the coupled port of third B41 coupler 93 or the coupled port of the fourth B41 coupler 95. It is appreciated that in certain embodiments the switch assembly 96A includes additional inputs, outputs, and/or switches. The switch assembly 96A also includes a CPL_IN switch 96A3, which is configured to select either the B3 power detector 92 or the B41 power detector 94.

A B41 filter 105 provides significant rejection outside of B41 and attenuates the B3 signal 88 significantly. Similarly, the B3/4/66 filter 104 provides significant rejection outside of B3/4/66 and attenuates the B41 signal 90 significantly. However, to further attenuate the B3 signal 88 in the power measurement acquired by the B41 power detector 94 and to further attenuate the B41 signal 90 in the power measurement acquired by the B3 power detector 92, one or more notch filters may be coupled to the isolated ports of the second B3 coupler 91 and the fourth B41 coupler 95. One or more notch filters may also or instead be included in a switch assembly. It should be appreciated that while the described example of FIG. 6 focused on bands 3 and 41 and which includes band select switches 108 and 110, aspects of the present disclosure are not so limited and may be used with other TDD and FDD channels, with and without band select switches as shown in FIG. 6.

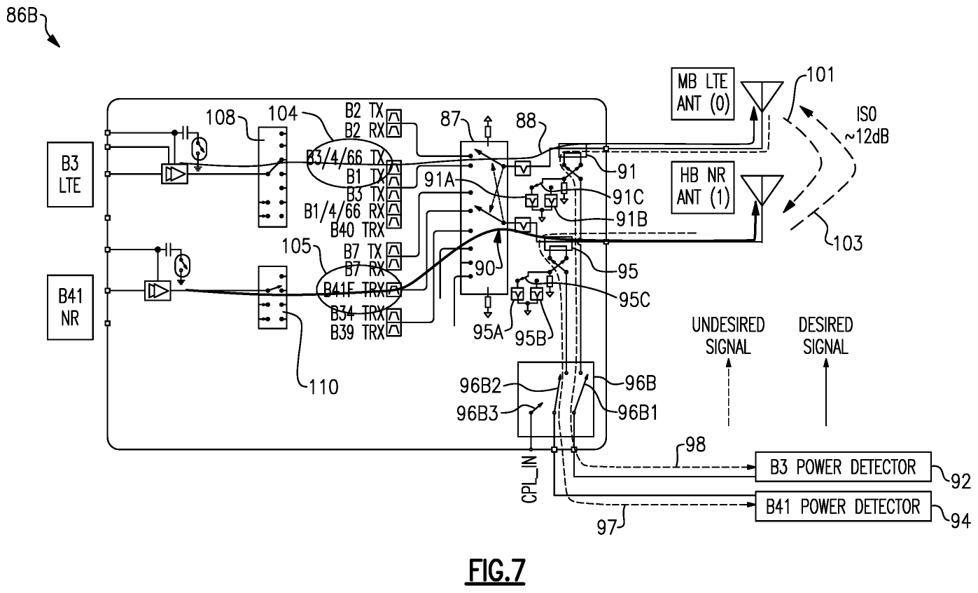

FIG. 7 illustrates an electronic system 86B which includes a switch assembly 96B and does not include the first B3 coupler 89 and the third B41 coupler 93. Each of the isolated ports of the second B3 coupler 91 and the fourth B41 coupler 95 is selectively coupled to one notch filter of a pair of notch filters arranged in parallel between ground and a switch coupled to the respective isolated port. The notch filters are arranged in parallel with a resistor. In at least one example, the resistor is a 50 Ohm resistor. The isolated port of the second B3 coupler 91 is selectively coupled via a switch 91C to one of a pair of notch filters including a first notch filter 91A and a second notch filter 91B. Similarly, the isolated port of the fourth B41 coupler 95 is selectively coupled via a switch 95C to one of a pair of notch filters including a third notch filter 95A and a fourth notch filter 95B. For each pair of notch filters, one of the two notch filters in the pair provides a notch in B3 and the other notch filter provides a notch in B41. Two notch filters are provided for each of the couplers 91, 95 because the electronic system 86B supports B3 and B41 from either of the antennas. In an example, the first notch filter 91A and the third notch filter 95A provide a notch in B3, and the second notch filter 91B and the fourth notch filter 95B provide a notch in B41. The selection of a particular notch filter isolates or at least significantly diminishes an undesired signal (e.g., the dashed line 97 or the dashed line 98) from reaching the switch assembly 96B (and consequently one of the power detectors 92, 94). Each notch filter may have an insertion loss of 20 dB or more. It is appreciated that the arrangements of notch filters described herein are not limited to only bands B3 and B41 and may also be applied to other bands with the notch filters being appropriately modified to eliminate or dimmish the appropriate bands where needed.

The switch assembly 96B includes a B3 switch 96B1 and a B41 switch 96B2. The B3 switch 96B1 is coupled to the B3 power detector 92 and the B41 switch 96B2 is coupled to the B41 power detector 94. The B3 switch 96B1 is configured to select the coupled port of the second B3 coupler 91 and the B41 switch 96B2 is configured to select the coupled port of the fourth B41 coupler 95. The switch assembly 96B also includes a CPL_IN switch 96B3, which is configured to select either the B3 power detector 92 or the B41 power detector 94.

In another embodiment, a selectable open connection is provided for the switch associated with each pair of notch filters (e.g., the switch 91C or the switch 95C) such that instead of selecting either notch filter to reject a particular band, the only component coupled between the isolated port and ground is the resistor when the switch is coupled to the open connection. Selection of the resistor termination rather than either the B3 or B41 filtered termination may be desirable when transmitting on only a single band, and not on multiple bands.

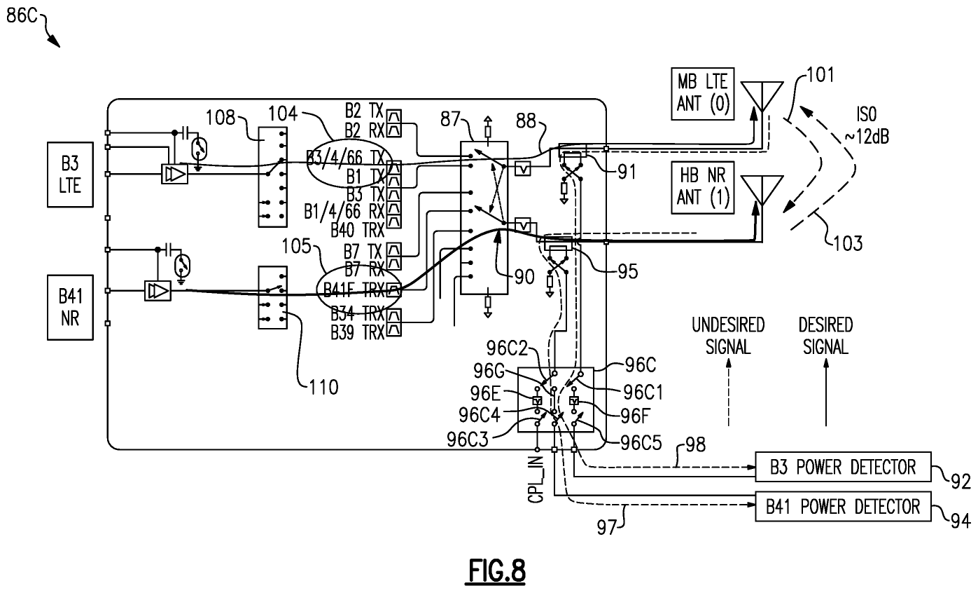

FIG. 8 illustrates an electronic system 86C which includes a switch assembly 96C and does not include the first B3 coupler 89 and the third B41 coupler 93. The switch assembly 96C includes a fifth notch filter 96E and a sixth notch filter 96F. In one example, the fifth notch filter 96E is configured to eliminate or diminish any unwanted B3 signal from reaching the B41 power detector 94 and the sixth notch filter 96F is configured to eliminate or diminish any undesired B41 signal from reaching the B3 power detector 92. Providing selectable notch filters in the switch assembly 96C provides a tradeoff for each power detector—to either (i) select the respective notch filter to reduce undesired signals at the expense of adding loss or (ii) to bypass the respective notch filter at the expense of undesired signals being detected by a power detector.

To select or bypass a particular notch filter, the switch assembly 96C includes a B3 filter selection switch 96C1 and a B41 filter selection switch 96C2. The B3 filter selection switch 96C1 is configured to select either the path including sixth notch filter 96F or a bypass path 96G which bypasses the fifth notch filter 96E and the sixth notch filter 96F. The B41 filter selection switch 96C2 is configured to select either the path including fifth notch filter 96E or the bypass path 96G. The switch assembly 96C includes a CPL_IN switch 96C3, which is configured to select either the B3 power detector 92 or the B41 power detector 94. The switch assembly 96C also includes a B41 power detector switch 96C4 coupled to the B41 power detector 94 and configured to select either the fifth notch filter 96E or the bypass path 96G, and a B3 power detector switch 96C5 coupled to the B3 power detector 92 and configured to select either the sixth notch filter 96F or the bypass path 96G.

In an example operation of the electronic system 86C, during SA/single band operation the output of the second B3 coupler 91 and the output of the fourth B41 coupler 95 would be routed from the coupler to the bypass path 96G and out to the respective power detector. During NSA (ENDC) operation, each EM coupler would be routed to the needed filter and then out to the selected power detector.

By incorporating notch filters in the arrangements as just described, cross-contamination of different frequency bands in the different power measurements is significantly reduced while still retaining the benefits of placing couplers both directly after the power amplifier and directly after the antenna switch module as described in embodiments provided herein. For example, power measurements from the chains 68′, 70′ shown in FIG. 5A experience less signal loss and/or corruption due to the addition of notch filters as described above. It is appreciated that the concepts and techniques described herein could be extended to other bands and other ENDC combinations.

Some of the embodiments described above have provided examples in connection with power amplifiers and/or mobile devices. Specifically, each of the electronic systems 2, 32, 34, 64, 65, 86A, 86B, 86C described herein may be included in a front-end module of a mobile device, such as a smart phone. However, the principles and advantages of the embodiments can be used for any other systems or apparatus, such as any uplink cellular device, that could benefit from any of the circuits described herein. Any of the principles and advantages discussed herein can be implemented in an electronic system with a need for detecting and/or monitoring a power level associated with an EM signal, such as forward EM power and/or a reverse EM power. Any of the switch networks and/or switch circuit discussed herein can alternatively or additionally be implemented by any other suitable logically equivalent and/or functionally equivalent switch networks. The teachings herein are applicable to a variety of power amplifier systems including systems with multiple power amplifiers, including, for example, multi-band and/or multi-mode power amplifier systems. The power amplifier transistors discussed herein can be, for example, gallium arsenide (GaAs), complementary metal oxide semiconductor (CMOS), or silicon germanium (SiGe) transistors. Moreover, power amplifiers discussed herein can be implemented by FETs and/or bipolar transistors, such as heterojunction bipolar transistors.

Aspects of this disclosure can be implemented in various electronic devices. Examples of the electronic devices can include, but are not limited to, consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a washer, a dryer, a washer/dryer, a peripheral device, a wrist watch, a clock, etc. Further, the electronic devices can include unfinished products.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A front-end module comprising:
a power amplifier configured to amplify a radio frequency signal, the power amplifier having an input configured to receive the radio frequency signal and an output configured to provide an amplified radio frequency signal;
a first coupler having an input port, an output port, a coupled port and an isolated port, the input port being coupled to the output of the power amplifier;
an antenna switch module having an input coupled to the output port of the first coupler and an output;
a second coupler having an input port, an output port, a coupled port and an isolated port, the input port of the second coupler being coupled to the output of the antenna switch module;
an antenna port configured to be coupled to an antenna, the antenna port being coupled to the output port of the second coupler; and
a first switch sub assembly to switchably connect one of the coupled port and the isolated port of the second coupler to an output of the first switch assembly and the other one of the coupled port and the isolated port of the second coupler to a first termination impedance.

2. The front-end module of claim 1 wherein the isolated port of the first coupler is connected to a second termination impedance.

3. The front-end module of claim 1 further comprising a second switch sub assembly to switchably connect one of the coupled port and the isolated port of the first coupler to an output of the second switch assembly and the other one of the coupled port and the isolated port of the first coupler to a second termination impedance.

4. The front-end module of claim 3, further comprising a filter connected between the output port of the first coupler and the input of the antenna switch module.

5. The front-end module of claim 4, further comprising a controller coupled to the first switch sub assembly and the second switch sub assembly and configured to connect the coupled port of the first coupler to the output of the second switch assembly and to connect the isolated port of the first coupler to the second termination impedance to obtain a first measurement from the output of the second switch assembly, the first measurement providing an indication of forward power provided by the power amplifier.

6. The front-end module of claim 5 wherein the controller is further configured to connect the coupled port of the second coupler to the output of the first switch assembly and to connect the isolated port of the second coupler to the first termination impedance to obtain a second measurement from the output of the first switch assembly, the second measurement providing an indication of forward power present on the antenna.

7. The front-end module of claim 5 wherein the controller is further configured to connect the isolated port of the second coupler to the output of the first switch assembly and to connect the coupled port of the second coupler to the first termination impedance to obtain a second measurement from the output of the first switch assembly, the second measurement providing an indication of power reflected from the antenna.

8. The front-end module of claim 7 wherein the controller is further configured to adjust an impedance of the antenna based on the indication of power reflected from the antenna.

9. The front-end module of claim 5 wherein the controller is further configured to obtain a first measurement from the output port of the first coupler and a second measurement from the output port of the second coupler.

10. The front-end module of claim 9 wherein the controller is further configured to linearize the amplified radio frequency signal by modifying, based on the first measurement and the second measurement, the radio frequency signal received by the power amplifier.

11. The front-end module of claim 9 wherein the controller is further configured to determine, based on the first measurement and the second measurement, an amplitude and a phase of a transfer function that describes a change in power of the amplified radio frequency signal between the power amplifier and the antenna.

12. The front-end module of claim 5 wherein the controller is further configured to:
operate the switch assembly to obtain a measurement of forward power provided to the antenna;
operate the switch assembly to obtain a measurement of reflected power from the antenna;
calculate a ratio between the measurement of forward power and the measurement of reflected power; and
adjust an amount of power provided by the power amplifier based on the calculated ratio.

13. The front-end module of claim 1 further comprising:
a second power amplifier configured to amplify a second radio frequency signal, the second power amplifier having an input configured to receive the second radio frequency signal and an output configured to provide a second amplified radio frequency signal;
a third coupler having an input port, an output port, a coupled port and an isolated port, the input port of the third coupler being coupled to the output of the second power amplifier and the output port of the third coupler being coupled to a second input of the antenna switch module;
a fourth coupler having an input port, an output port, a coupled port and an isolated port, the input port of the fourth coupler being coupled to a second output of the antenna switch module; and
a second antenna port configured to be coupled to a second antenna, the second antenna port being coupled to the second output of the second coupler.

14. The front-end module of claim 13 wherein:
the power amplifier, the first coupler, the second coupler, and the antenna port form a first chain;
the second power amplifier, the third coupler, the fourth coupler, and the second antenna port form a second chain; and
the amplified radio frequency signal of the first chain is in a different frequency band than the second amplified radio frequency signal of the second chain.

15. The front-end module of claim 14, wherein the amplified radio frequency signal and the second amplified radio frequency signal are transmitted at the same time.

16. The front-end module of claim 1 wherein the radio frequency signal received by the input of the power amplifier has a frequency in one of a range of about 600 MHz to about 2.5 GHz, a range of about 450 MHz to about 6 GHz, and a range of about 24 GHz to 52 GHz.

17. The front-end module of claim 1 wherein the first coupler is a unidirectional coupler and the second coupler is a bidirectional coupler.

18. A front-end module comprising:
a power amplifier configured to amplify a radio frequency signal, the power amplifier having an input configured to receive the radio frequency signal and an output configured to provide an amplified radio frequency signal;
a first coupler having an input port, an output port, a coupled port and an isolated port, the input port being coupled to the output of the power amplifier;
an antenna switch module having an input coupled to the output port of the first coupler and an output;
a second coupler having an input port, an output port, a coupled port and an isolated port, the input port of the second coupler being coupled to the output of the antenna switch module;
an antenna port configured to be coupled to an antenna, the antenna port being coupled to the output port of the second coupler; and
a first switch sub assembly to switchably connect one of the coupled port and the isolated port of the second coupler to an output of the second switch assembly and the other one of the coupled port and the isolated port of the second coupler to a second termination impedance, or to connect each of the coupled port and the isolated port of the second coupler to the second termination impedance.

19. The front-end module of claim 18 wherein the isolated port of the first coupler is connected to a second termination impedance.

20. The front-end module of claim 18 further comprising a second switch sub assembly to switchably connect one of the coupled port and the isolated port of the first coupler to an output of the second switch assembly and the other one of the coupled port and the isolated port of the first coupler to a second termination impedance.

21. The front-end module of claim 20, further comprising a filter connected between the output port of the first coupler and the input of the antenna switch module.

22. The front-end module of claim 21, further comprising a controller coupled to the first switch sub assembly and the second switch sub assembly and configured to connect the coupled port of the first coupler to the output of the second switch assembly and to connect the isolated port of the first coupler to the second termination impedance to obtain a first measurement from the output of the second switch assembly, the first measurement providing an indication of forward power provided by the power amplifier.
